(19) United States
(12) Patent Application Publication
(10) Pub. No.: US 2015/0310904 A1
(43) Pub. Date: Oct. 29, 2015

(54) SYSTEM AND METHOD OF CONCURRENT READ/WRITE MAGNETO-RESISTIVE MEMORY

(71) Applicant: QUALCOMM Incorporated, San Diego, CA (US)

(72) Inventors: Taehyun KIM, San Diego, CA (US); Jung Pill KIM, San Diego, CA (US); Sungryul KIM, San Diego, CA (US); Xiangyu DONG, San Diego, CA (US)

(73) Assignee: QUALCOMM Incorporated, San Diego, CA (US)

(21) Appl. No.: 14/263,632

(22) Filed: Apr. 28, 2014

(51) Int. Cl. G11C 11/16

(52) U.S. Cl. CPC G11C 11/1659; G11C 11/1693; G11C 11/1653; G11C 11/1673; G11C 11/1675

(57) ABSTRACT

In a memory having a first memory cell array, a second memory cell array, an address is received on an address port. Based on the address, an internal address is transmitted, and it is latched and held for a first interval as a first array address. The first memory cell array is accessed over the first interval, based on the first array address. Another address is received at the address port, during the first interval, and another internal address is transmitted, and latched and held for a second interval that overlaps the first interval, as a second array address. The second memory cell array is accessed during the second interval, based on the second array address.

### FIELD OF DISCLOSURE

The technical field of the disclosure relates to magneto-resistive memory and more specifically, to read and write access to magneto-resistive memory elements within random access memory (RAM) arrays.

### BACKGROUND

Magneto-resistive memory (hereinafter “resistive memory”) is considered a promising technology for next generation non-volatile memory, as potential features include fast switching, high switching cycle endurance, low power consumption, and extended unpowered archival storage.

A conventional resistive memory element includes a “fixed” magnetization layer and a “free” magnetization layer that is switchable between two mutually opposite, stable magnetization states—one being “parallel” (P) to the magnetization of the fixed layer, and the other being opposite, or anti-parallel” (AP), to the fixed magnetic layer. The resistive memory element has an electrical resistance in its P state lower than its resistance when in its AP state. The P-AP state of the resistive element can therefore be read by detecting its resistance. By assigning one of the P and AP states to represent a first binary value, e.g., a “0”, and the other to represent a second binary value, e.g., a “1” the resistive memory element can be a binary, i.e., one-bit storage.

Applications of resistive memory include random access memory (RAM) formed of arrays of individually addressable resistive memory elements. Such memory devices can be referred to a resistive memory RAM or “MRAM.”

One characteristic of resistive memory elements can be the write speed being significantly slower than the read speed. A general reason is that switching the free magnetization layer to a desired one of its P and AP states may require passing a write current through the resistive memory element that, in addition to having greater magnitude than the read current, must be maintained for a substantially longer duration.

In certain applications, for example, multiple-port cache memory differences between read and write speed can incur contention and delay costs, for example, wait time placed on read operations. Such delays can cause system degradation.

### SUMMARY

Exemplary embodiments provide, among other features and benefits, write-while-write, read-while-write, and read-while read enabling concurrent access of multiple sub-banks of a single-port multiple sub-bank MRAM. Among other features and benefits, read-while-write aspects of exemplary embodiments can avoid system delay due to write accesses being significantly longer in duration that read accesses. Among further features and benefits, read-while-read aspects of exemplary embodiments can provide a doubling, or further increase in read access rate, without necessitating costly techniques of reducing MRAM read access time.

One example environment for example methods according to one or more embodiments can include a memory having a first memory cell array, a second memory cell array, a data in port, a data out port, and a command/address port. Features of example methods, for read or read/write, can include receiving a clock, wherein the clock includes a first edge, a second edge and a third edge, spaced apart by a clock period, and receiving, in association with the first edge, a command at the command/address port to access a memory cell in the first memory cell array. Features of example methods can further include, in response to the command to access a memory cell in the first memory cell array, accessing the memory cell over a first interval, wherein the first interval begins prior to the second edge and extends past the second edge. In an aspect, features of example methods can include receiving, in association with the second edge, a command at the command/address port to access a memory cell in the second memory cell array. Further to that aspect, features of example methods can include, in response to the command to access a memory cell in the second memory cell array, accessing said memory cell over a second interval, wherein the second interval overlaps the first interval.

In an aspect, features of example methods according to one or more exemplary embodiments can further include, in association with the first edge, receiving a data in, and the command to access a memory cell in the first memory cell array can include a command to write the data in to the memory cell in the first memory cell array. In an aspect, features of example methods can further include writing the data in to the memory cell over the first interval and, according to one aspect, the first interval can be a write interval, and the write interval can extend past the third edge.

In an aspect, in one example operation of example methods according to one or more exemplary embodiments, the clock can further include a fourth edge spaced one clock period after the third edge. In a further aspect, features of example methods can also include receiving, in association with the third edge, another data in and a command to write the another data in to a memory cell in the second memory cell array. In an aspect, further features of example methods can include, in response to the command to write the another data in to a memory cell in the second memory cell array, writing the another data in to the memory cell over a third interval, and the third interval can overlap the first interval by more than one clock period.

Another environment for other example methods according to one or more embodiments can include a memory having a first memory cell array, a second memory cell array, a data in port, and an address port. Features of example methods can include receiving an address on the address port and, based on the address, transmitting an internal address, receiving the internal address by a first address latch and holding the internal address on the first address latch as a first array address, over a first interval. In an aspect, features of example methods can include accessing the first memory cell array, during the first interval, based on the first array address. In an aspect, features of example methods can also include receiving another address on the address port and, based on the another address, transmitting another internal address. Features of example methods can further include receiving the another internal address by a second address latch and holding the another internal address on the second address latch as a second array address, over a second interval. In an aspect, the second interval can overlap the first interval. Features of example methods according to one or more exemplary embodiments can include accessing the second memory cell array, during the second interval, based on the second array address.

In one example resistive memory cell device according to one or more exemplary embodiments, features can include an address bus and a control block configured to receive an externally generated address, a command and a clock and, in response, transmit an internal address on the address bus, and generate a first sub-bank address latch control and a second sub-bank address latch control. Example features can further include a first sub-bank having a first array of resistive memory cells and a first sub-bank latching address circuitry that can be configured to access a resistive memory cell in the first array of resistive memory cells according to a value of the internal address and maintain the access over a first interval based on the first sub-bank address latch control. Example features, according to one or more exemplary embodiments can further include a second sub-bank having a second array of resistive memory cells and a second latching array address circuitry that can be configured to access a resistive memory cell in the second array of resistive memory cells according to an updated value of the internal address and maintain said access over a second interval based on the second sub-bank address latch control. In an aspect, the control block can be configured to generate the first sub-bank address latch control and the second sub-bank address latch control so that the second interval overlaps the first interval.

In aspect, the first array of resistive memory cells can include a plurality of first array word lines and a plurality of first array bit lines, and resistive memory cells associated with intersections of the first array word lines and first array bit lines. In a further aspect, features of the first sub-bank latching access circuitry can include a first sub-bank address latch having an input coupled to the address bus, and a first sub-bank address latch output, a first array row decoder configured to receive a row field of the first sub-bank address latch output and, in response to a value of the row field, enable a corresponding one of the first array word lines, and a first array bit line selector configured to receive a bit field of the first sub-bank address latch output and, in response to a value of the bit field, enable a corresponding one of the first array bit lines.

### BRIEF DESCRIPTION OF THE DRAWINGS

The accompanying drawings found in the attachments are presented to aid in the description of embodiments of the invention and are provided solely for illustration of the embodiments and not limitation thereof.

FIG. 1 shows a simplified schematic of a single-port multiple-bank MRAM.

FIG. 2A shows one simulated timing diagram of example read and write access of the FIG. 1 single-port multiple sub-bank MRAM in accordance with various exemplary embodiments.

FIG. 2B shows one simulated timing diagram of example sequential read operations on the FIG. 1 single-port multiple sub-bank MRAM in accordance with various exemplary embodiments.

FIG. 3 shows a functional block schematic of one example multiple concurrent sub-bank access MRAM in accordance with various exemplary embodiments.

FIG. 4 shows a functional block schematic of one example controller block for one multiple concurrent sub-bank access MRAM in accordance with various exemplary embodiments.

FIG. 5 shows one simulated timing diagram of example read-while-write and write-while-write access on one example multiple concurrent sub-bank access MRAM in accordance with various exemplary embodiments.

FIG. 6 shows one simulated timing diagram of example read-while-read access on one example multiple concurrent sub-bank access MRAM in accordance with various exemplary embodiments.

FIG. 7 shows a functional block schematic of one example multiple concurrent sub-bank access MRAM in accordance with one alternative exemplary embodiment.

FIG. 8 illustrates one exemplary wireless communication system in which one or more embodiments of the disclosure may be advantageously employed.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields, electron spins particles, electrospins, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. In accordance with the interchangeability of hardware and software for implementing aspects, various illustrative components, blocks, modules, circuits, and steps are described generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

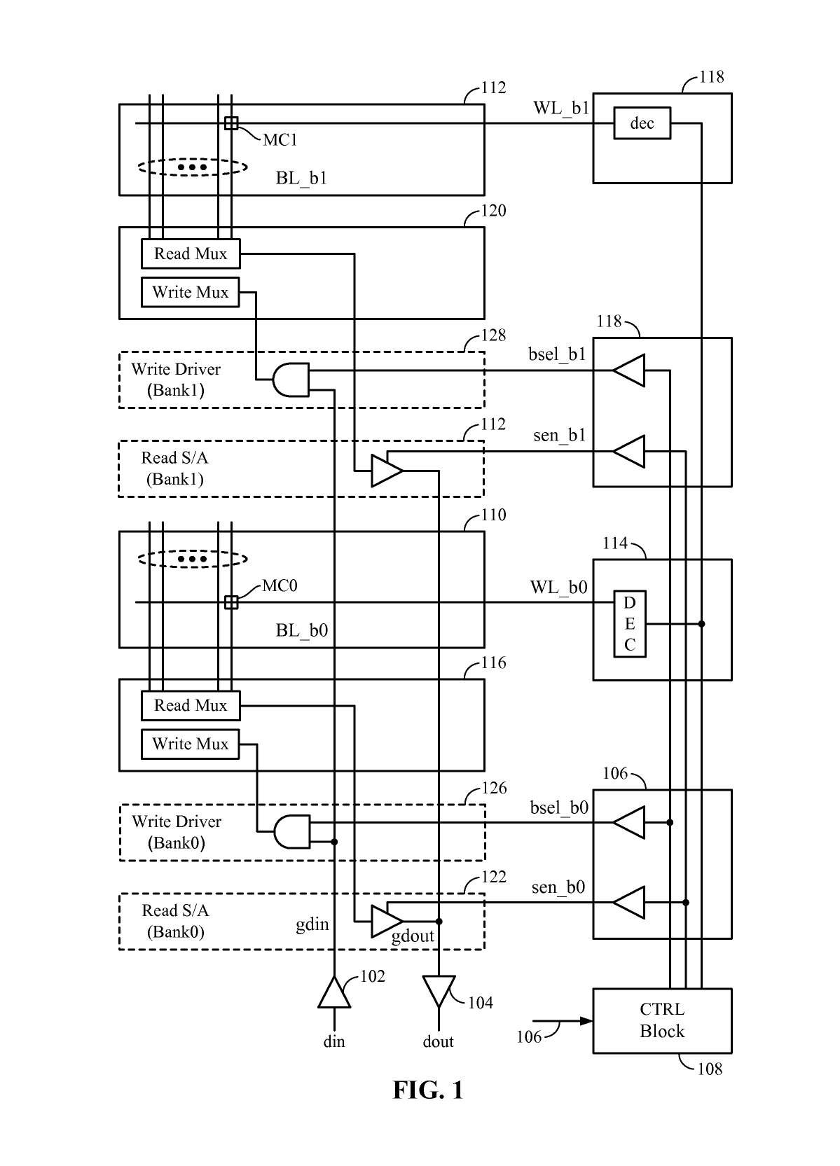

FIG. 1 shows a functional block schematic 100 of one example single-port multiple-bank MRAM (hereinafter referred to as “SP/MB MRAM 100”). The term “single-port” is used because the SP/MB MRAM 100 has a single data-in port, provided by the data input buffer 102, and a single data-out port, provided by the data output buffer 104, and a single address/command port (ADDR/CMD) port 106. The ADDR/CMD port 106 receives, and feeds to a control block 108 an externally generated clock, CLK, read/write address ADDR, and command CMD. For purposes of this description, it will be assumed that CMD can be a read command or a write command.

Continuing to refer to FIG. 1, the SP/MB MRAM 100 includes a first sub-bank 110 of MRAM cells and a second sub-bank 112 of MRAM cells, each being a row-column access array of MRAM cells, having M rows (e.g., word lines) and N columns or bit lines. The first sub-bank 110 has an associated first sub-bank decoder 114 that, for example, based on a row field (not explicitly labeled) of the ADDR selects among a plurality of M word lines, of which an exemplary one word line is shown and labeled WL_b0. The first sub-bank 110 has an associated first bank read/write bit line selector 116 (hereinafter “first sub-bank R/W BL selector” 116) that based, for example, on a column field “CF_0” of the ADDR, selects a bit line among a plurality of (e.g., N) bit lines (shown but not separately labeled). Bit line selection functions of the first sub-bank R/W BL selector 116 can be provided by, for example, a read multiplexer and a write multiplexer (shown but not separately numbed).

In like manner, the second sub-bank 112 has a second sub-bank decoder 118 that based, for example, on a row field (not explicitly labeled) of the ADDR selects among a plurality of (e.g., M) word lines, of which an exemplary one word line is shown and labeled WL_b1. The second sub-bank 112 has an associated second bank read/write bit line selector 120 (hereinafter “second sub-bank R/W BL selector” 120) that based, for example, on a column field “CF_1” of the ADDR, selects a bit line among a plurality of (e.g., N) bit lines (shown but not separately labeled). Bit line selection of the second sub-bank R/W BL selector 120 can be provided by, for example, a read multiplexer and a write multiplexer (shown but not separately numbed).

The read multiplexer of each of the first sub-bank R/W BL selector 116 and second sub-bank R/W BL selector 120, when operative, is an N:1 (N being the number of bit lines) switch. The N:1 switch operation selects one of the N bit lines of its corresponding sub-bank (i.e., first sub-bank 110 or second sub-bank 112) for input to that sub-bank's sense amplifier (S/A), i.e., the first sub-bank sense amplifier 122 (hereinafter “first sub-bank S/A amplifier 122”) or the second sub-bank sense amplifier 124 (hereinafter “second sub-bank S/A amplifier 124”). Only one of the first sub-bank S/A 122 and second sub-bank S/A 124 can be enabled at a time, since their respective outputs (not separately numbered) are connected together as the “gdout” signal that feeds the data output buffer 104. The selective enabling of the first sub-bank S/A 122 and second sub-bank S/A 124 can be provided by the “sen_b0” and “sen_b1” signals, described later in further detail.

Referring to FIG. 1, the input of the write multiplexer of the first sub-bank R/W BL selector 116 is fed by the selectively enabled write driver 126 of the first sub-bank 110, hereinafter “first sub-bank SE write driver 126”. In like manner, the input of the write multiplexer of the second sub-bank R/W BL selector 120 is fed by the selectively enabled write driver 128 of the second sub-bank 112, hereinafter “second sub-bank SE write driver 128.” Enabling logic of the first sub-bank SE write driver 126 and the second sub-bank SE write driver 128 can be represented as an AND gate (shown but not separately numbered). The first sub-bank SE write driver 126 and the second sub-bank SE write driver 128 are enabled in a sub-bank selective manner by the “bsel_b0” and “bsel_b1” write enable signals, respectively. In the FIG. 1 example, a first sub-bank read/write enable logic 130 generates the bsel_b0 and the sen_b0 signal described previously, based on control signals from the control block 108. Likewise, a second sub-bank read/wrote enable logic 132 generates the bsel_b1 and the sen_b1 signal described previously, based on control signals from the control block 108.

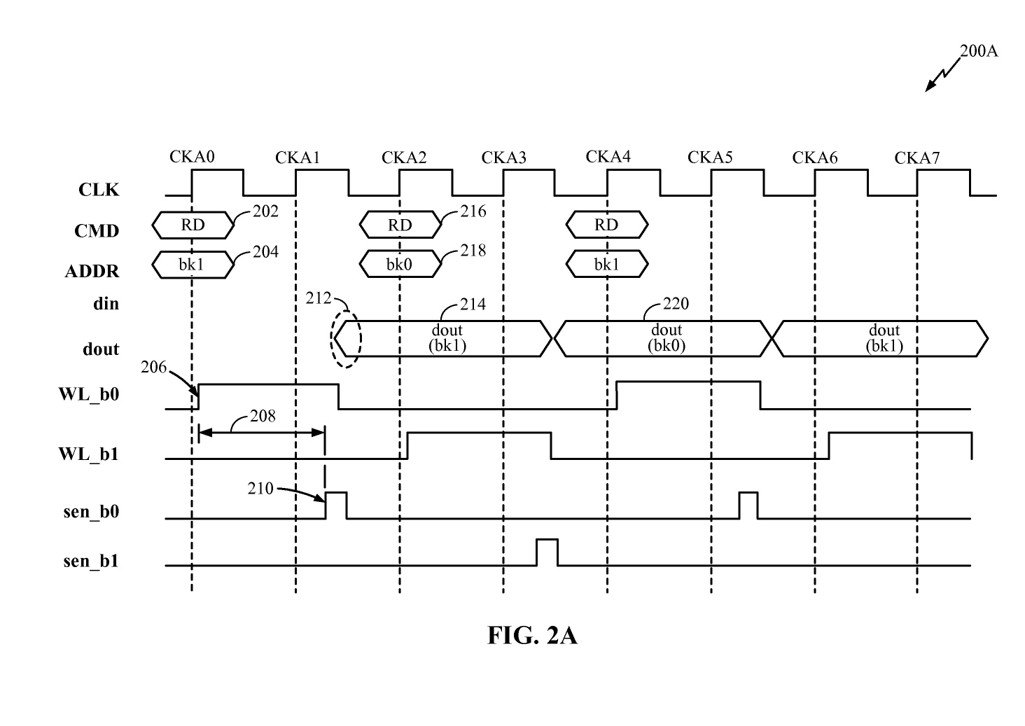

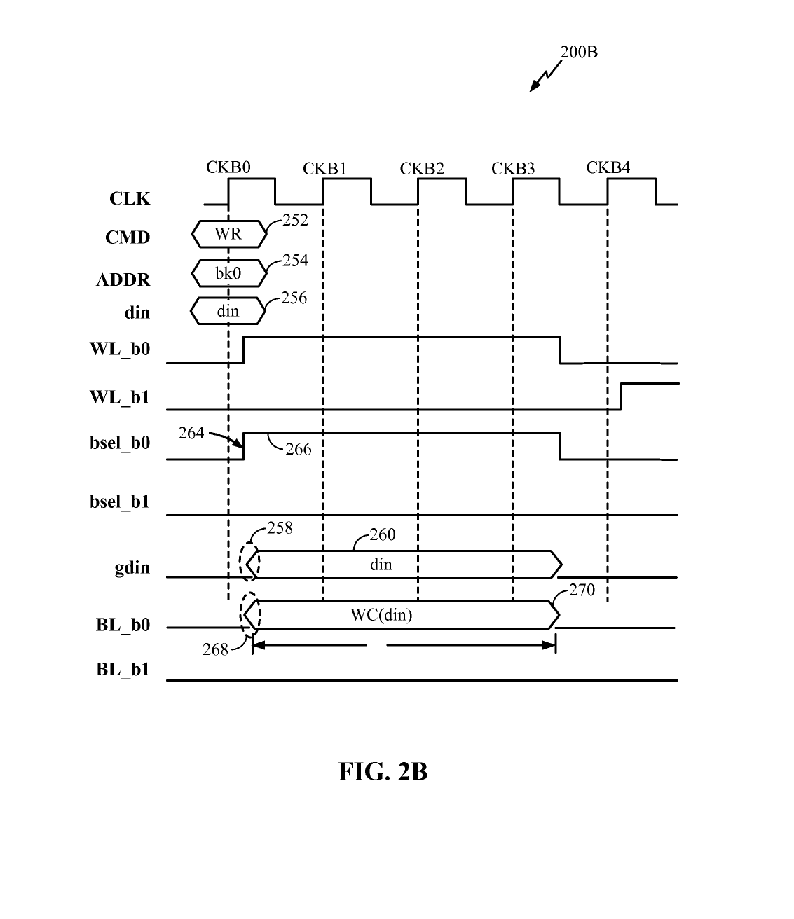

A sequence of two read accesses on the FIG. 1 SP/MB MRAM 100 will now be described in reference to the FIG. 2A simulated timing diagram (hereinafter referred to as “timing diagram”) 200. Referring to FIG. 2A, the timing diagram 200 shows the read operations relative to a sequence of eight leading edges (hereinafter “edges”) of CLK received by the control block 108. The edges are labeled, respectively, “CKA0, CKA1 . . . CKA7.” The examples label read commands received at the ADDR/CMD port 106 as “RD.”

Referring to FIG. 2A, at a time (shown but not separately labeled) preceding CKA0 sufficient to meet device-specific set-up, a RD 202 with write address value bk1 204 is received at the ADDR/CMD port 106. The control block 108, in response, passes a row or word line field (not separately shown) of bk1 204 to the first sub-bank decoder 114 and to the second sub-bank decoder 118. Likewise, the control block 108 may send a column or bit line field (not separately shown) of bk1 204 to the respective read multiplexers in the first sub-bank R/W BL selector 116 and to the second sub-bank R/W BL selector 120. Since bk1 204 is the address for MC1, which is in the second sub-bank 112, it will be assumed that one bit of bk1 202 selects or is recognized by the second-bank decoder 118, but is not recognized by or does not enable the first-bank decoder 114. At time 206, which may be some decoder latency (shown but not separately labeled) after CKA0, the second sub-bank decoder 118 enables the MC1 word line WL_b1. Concurrently, the read multiplexer of the second sub-bank R/W BL selector 120 selects (an action not explicitly visible in the FIG. 2A timing diagram 200A) the bit line of MC1 and connects it to the input of the second sub-bank S/A 124.

Continuing to refer to FIGS. 1 and 2A, a result of the above-described enabling of WL_b1 and of the MC1 bit line is the forming of a read voltage (not explicitly labeled on the FIG. 2A timing diagram 200A) at the input of the second sub-bank S/A 124. The read voltage corresponds to the magnetization of MC1 and is compared to a reference voltage (not explicitly shown on FIG. 1) by the second sub-bank S/A 124 to generate a corresponding read result “gdout.” The second sub-bank S/A 124 may use conventional sense amplifier techniques that are known to persons of ordinary skill in the art and, therefore, further detailed description is omitted.

For reasons including electrical characteristics of MC1, a settling time 208 is required for the read voltage to enable sufficient sensing accuracy by the second sub-bank S/A 124. Reasons for the settling time 208 are known to persons of ordinary skill in the art and, therefore, further detailed description is omitted. The sum of the time 206 and the settling time 208 may be referred to as a “read latency” (not separately labeled on FIG. 2A). For this example, it will be assumed that the read latency is greater than the period CP of CLK. Therefore, time 210 at which the control block 108 generates sen_b1 to enable the second sub-bank S/A 124 is after CKA1. The second sub-bank S/A 124, in response, generates at time 212 a data value labeled “dout(bk1)” 214.

Continuing with the example read of MC1 that started at CKA0, at CKA2—two CLK cycles after CKA0—the read value dout(bk1) appears at the output of the data output buffer 104. Therefore, at CKA2, the internal access capabilities of SP/MB MRAM 100 are now freed. Accordingly, in this example, at CKA2 another read request, shown as RD 216 with read address “bk0” 218, can be presented to the control block 108. The SP/MB MRAM 100 can then perform another read operation, and generate a corresponding dout(bk0) at 220, which is at CKA4—two CK cycles after CKA2. Examples of succeeding, like-manner read operations are shown but not separately numbered.

As described, the read latency spans two CLK cycles, i.e., from CKA0 to CKA2. Since SP/MB MRAM 100 is a single port device, this read latency means that for two CLK cycles the device is not available as a memory resource to other operations, even if such operations are an access to the other, i.e., first sub-bank 110. Therefore, for SP/MB MRAM 100, the maximum read access rate is one-half the CLK frequency.

One potential solution to this read access rate limit of one-half the CLK frequency can include latency reduction methods, such as layout optimization, and/or tighter fabrication tolerances, to reduce the latency to less than one CLK cycle. However, conventional single-port, multiple sub-bank MRAM techniques can also have a write latency limitation. More particularly, according to conventional MRAM techniques, obtaining acceptable storage accuracy, e.g., bit error rate, may require a write current duration significantly longer than the duration for the read current. One example is later described in reference to FIG. 2B. Read latency reduction methods such as the examples identified above do not necessarily obtain like reduction in the required write current duration. Accordingly, access bottlenecks may remain.

The above-identified write latency limitation of conventional single-port, multiple sub-bank access devices will be illustrated by an example sequence of write and read access on the FIG. 1 SP/MB MRAM 100. The example sequence will be described in reference to the FIG. 2B simulated timing diagram (hereinafter referred to as “timing diagram 200B”). To further illustrate write latency as an access limiter, the timing diagram 200B assumes the FIG. 1 SP/MB MRAM 100 has been optimized (e.g., tighter layout rules) to have a one CLK read latency. The timing diagram 200B shows read and write accesses in relation to another sequence of CLK edges, labeled “CKB0, CKB1 . . . CKB7.”

Referring to FIG. 2B, at a time (shown but not separately labeled) preceding CKB0 sufficient to meet set-up, a WR (write command) 252 and write address value bk0 254 are received at the ADDR/CMD port 106, and a corresponding din 256 is received at the data input buffer 102. The write address value bk0 254 is assumed, for this example, to be the address for the cell MC0 in the first sub-bank 110. The data input buffer 102, in response to din 256, outputs at 258 a corresponding “gdin” 260. The gdin 260 may be received by both the first sub-bank write driver 126 and the second sub-bank write driver 128. The control block 108, in response to bk0 254, passes the row address field of bk0 254 to the first sub-bank decoder 114 and the second sub-bank decoder 118, and a column or bit line field of bk0 to the first sub-bank R/W BL selector 116 and the second sub-bank R/W BL selector 120. The first sub-bank decoder 114 recognizes bk0 254 (being to MC0 in the first sub-bank 110) and decodes a row field of bk0 254. At time 262 (e.g., a decoder latency after CKB0), based on a result of the decoding, the first sub-bank decoder 114 enables the MC0 word line w1_b0. Similarly, at approximately time 262, the first sub-bank R/W BL selector 116, based on decoding a column or bit line field of bk0 254 couples an output of the first sub-bank driver 126 to the bit line of MC0. The second sub-bank decoder 118 does not recognize, or is not enabled by bk0 254. Concurrently, or approximately concurrently, the control block 108 generates, or controls the first sub-bank read/write enable logic 130 to generate, at 264, a first sub-bank write enable, bsel_b0 266. The bsel_b0 266 signal enables the first sub-bank SE write driver 126. Therefore, starting at 268, the first sub-bank SE write driver 126, now enabled, pushes (or sinks) a write current, “WC (din)” 270, through the bit line BL_b0 and through the enabled MC0. In accordance with conventional MRAM writing technique, the magnitude and direction of WC (din) 270 depends on gdin.

Continuing with the example write access that started at CKB0, in accordance with conventional MRAM write techniques, to attain acceptable writing accuracy, e.g., bit error rate, the duration WDT of the write current WC (din) 270 is generally significantly longer than required for read current. The specific value of WDT can be application-specific, and may be determined by combinations of factors for which description is beyond the subject matter pertinent to understanding the embodiments. However, it may be significantly longer than the read duration. For illustrative purposes, the timing diagram 200B shows WDT greater than three CLK periods. As can be seen, a result is that the write MC0 that started at CKB0 prevents the FIG. 1 SP/MB MRAM 100, until the fourth CLK edge after CKB0, from receiving another access CMD and ADDR at the ADDR/CMD port 106 until CKB4, even to access the second sub-bank 112. Further, if the access presented at CKB4 is a write access, the SP/MB MRAM 100 will again be unavailable until the fourth CLK edge after CKB4.

One example resistive memory cell device according to one or more exemplary embodiments can include an address bus, a controller configured to receive an external address, a command and a clock and, in response, transmit an internal address on the address bus, and generate a first sub-bank address latch control and a second sub-bank address latch control. In an aspect, one example memory device can include a first sub-bank and a second sub-bank. In one further aspect, the first sub-bank can have a first array of resistive memory cells and a first sub-bank latching access circuitry. In an aspect, the first sub-bank latching address circuitry can be configured to access a resistive memory cell in the first array of resistive memory cells according to a value of the internal address and maintain the access over a first interval based on the first sub-bank address latch control. In a related aspect, the second sub-bank can have a second array of resistive memory cells and a second latching array address circuitry. Further to this example, the second latching array access circuitry can be configured to access a resistive memory cell in the second array of resistive memory cells according to an updated value of the internal address and maintain that access over a second interval. In an aspect, the second interval can be based on the second sub-bank address latch control, and further to this aspect, the control block can be configured to generate the first sub-bank address latch control and the second sub-bank address latch control so that the second interval overlaps the first interval.

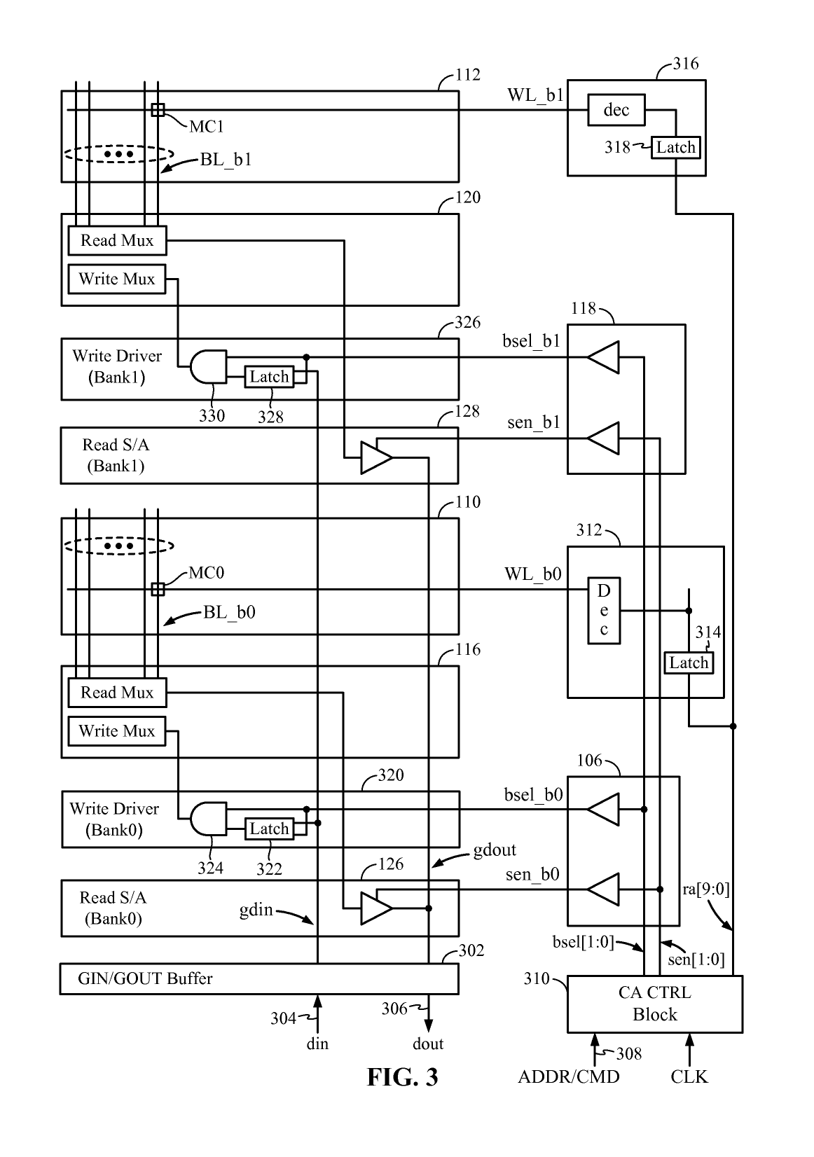

FIG. 3 shows a functional block schematic 300 of one example multiple concurrent sub-bank access MRAM in accordance with various exemplary embodiments. It will be understood that the FIG. 3 functional block schematic 300 represents groupings of logical operations and functions, and not hardware topology or arrangement, except where explicitly stated, or where made clear from a particular context to mean otherwise. For brevity, the phrase “multiple concurrent sub-bank access” will hereinafter be abbreviated “MCA.” Example operations and aspects refer to “MCA MRAM” 300, which means: “circuitry and/or related software modules of computer-executable instructions configured to perform the logical functions including examples shown in the FIG. 3 functional block schematic 300.”

To avoid possible obfuscation of concepts by detailed description of new example blocks not necessarily specific to the embodiments, the example MCA MRAM 300 uses certain blocks from the FIG. 1 SP/MB MRAM 100. Like blocks are labeled in like manner. The MCA MRAM 300, for example, uses the first sub-bank 110, the second sub-bank 112, the second first-bank decoder 114, the second sub-bank decoder 118, the first sub-bank R/W BL selector 116 and the second sub-bank R/W BL selector 120.

Referring to FIG. 3, the MCA MRAM 300 has a “GIN/GOUT” data interface buffer 302 with a single data input port, such as data-in port 304 and a single data output port, such as the data-out port 306. A single address/command port, such as address/command (ADDR/CMD) port 308, receives the previously described externally generated read/write address ADDR and command CMD. Example CMDs used in this description include RD (read command) and WR (write command). The ADDR/CMD port 308 feeds ADDR and CMD to a concurrent access (hereinafter “CA”) control block 310. Among other functions that are later described, the CA control block 310 may be configured to generate and transmit or distribute, for example on a bus termed the “concurrent access address” (CAA) bus, an internal access address corresponding to the ADDR. The CA control block 310 may perform a partial translation or partial decoding of the address received at the ADDR/CMD port 308 prior to transmitting a corresponding internal access address on the CAA bus. Various conventional techniques for such partial translating or partial decoding are known to persons of ordinary skill in the relevant art and, therefore, further detailed description is omitted. It will be assumed—except where expressly stated otherwise or where made clear from the context to be otherwise—that the internal access address the CA control block 310 generates for an address to a memory cell received at the ADDR/CMD port 308 is decodable to the word line and the bit line of that memory cell. Therefore, whether the internal access address transmitted on the CAA bus is an exact repetition of the address received at the ADDR/CMD port 308 or a translated (in whole or in part) version of the same, is immaterial.

Continuing to refer to FIG. 3, in an aspect the MCA MRAM 300 may include a first sub-bank address (ADDR) latch 312 that may be fed by the CAA bus and a second sub-bank address (ADDR) latch 314, which also may be fed by the CAA bus. In an example according to one aspect, the first sub-bank ADDR latch 312 and the second sub-bank ADDR latch 314 can be configured to latch the entire width of the CAA bus. Alternative latching aspects are described in further detail at later sections. In the example that latches the entire width of the CAA bus, a row or word line field of the output of the first sub-bank ADDR latch 312, represented as a line (not separately numbered), can feed the first sub-bank decoder 114. Similarly, a column or bit line field of the output of the first sub-bank ADDR latch 312, such as the previously described CF_0, can feed the first sub-bank R/W BL selector 116. In like manner, in the example latching the entire width of the CAA bus, a row or word line field of the output of the second sub-bank ADDR latch 314, represented as a line (not separately numbered) can feed the second sub-bank decoder 118. A column or bit line field, such as the example labeled CF_1, can feed the second sub-bank R/W BL selector 120.

In an aspect, the first sub-bank ADDR latch 312 and the second sub-bank ADDR latch 314 may be implemented as transparent pulse latches. Implementation as transparent pulse latches can provide, for example, immediate pass through to the outputs of the first sub-bank ADDR latch 312 and the first sub-bank ADDR latch 314 without waiting for a CLK edge and, after latching, maintaining the latch output state irrespective of changes on the CAA bus. Various techniques for transparent pulse latches are known, and can be adapted to this disclosure by persons of ordinary skill in the art without undue experimentation. Detailed description of their implementation is therefore omitted. It will be understood that embodiments are not limited to transparent pulse latch implementation of the first sub-bank ADDR latch 312 and the second sub-bank ADDR latch 314. On the contrary, upon reading this disclosure persons of ordinary skill in the art can adapt the example operations to implementations with fully clocked, non-transparent multiple bank latches, without undue experimentation.

In an aspect, described in further detail in later sections, the CA control block 310 can be configured to dynamically control, according to various sequences of CMDs, the latching and the transparency state of the first sub-bank ADDR latch 312 and the second sub-bank ADDR latch 314. As will be appreciated from this disclosure, configurations of the CA control block 310 for controlling the latching and the transparency of the first sub-bank ADDR latch 312 and the second sub-bank ADDR latch 314 can provide the MCA MRAM 300 the capability, while accessing one of the first sub-bank 110 and the second sub-bank 112, of accessing the other.

The first sub-bank R/W BL selector 116, the second sub-bank R/W BL selector 120, the first sub-bank S/A 122 and the second sub-bank S/A 124 can be as previously described.

Circuitry according to the MCA MRAM 300 can provide one example implementation of a first sub-bank having a first array of resistive memory cells and a first sub-bank latching access circuitry, and a second sub-bank having a second array of resistive memory cells and a second sub-bank latching access circuitry. One example implementation of the first array of resistive memory cells can include the first sub-bank 110, and one example implementation of the second array of resistive memory cells can include second sub-bank 112. One example implementation of the first sub-bank latching address circuitry can include the first sub-bank ADDR latch 312, the first sub-bank decoder 114, and the first sub-bank R/W BL selector 116. One example implementation of the second sub-bank latching address circuitry can include the second sub-bank ADDR latch 314, the second sub-bank decoder 118, and the second sub-bank R/W BL selector 120.

Continuing to refer to FIG. 3, the MCA MRAM 300 can include, further to aspects of writing to the first sub-bank 110 with concurrent read or write of the second first sub-bank 110, a first sub-bank latching write driver 316. In an aspect, the first sub-bank latching write driver 316 can include a first sub-bank gdin latch 318 and a first sub-bank write driver enabling logic 320. The MCA MRAM 300 can also include, further to aspects of selective write to the second sub-bank 112 with concurrent read or write of the first sub-bank 110, a second sub-bank latching write driver 322 having a second sub-bank gdin latch 324 and a second sub-bank write driver enabling logic 326.

In an aspect, as described in further detail in later sections, the CA control block 310 may be configured to control the first sub-bank gdin latch 318 and the second sub-bank gdin latch 328 to selectively latch the gdin bus having the din received at the data-in port 304. Among other features and benefits, this aspect, in combination with the CA control block 310 selectively controlling the first sub-bank ADDR latch 312 and the second sub-bank ADDR latch 314, can provide the MCA MRAM 300 with various read-while-write or write-while-write capabilities. For example, in operations according to one aspect, the first sub-bank gdin latch 318 can latch a din as a “latched write data.” The latched write data output by the first sub-bank gdin latch can provide continued writing of that data to the first sub-bank 110, thereby freeing the gdin bus for another din for writing to the second sub-bank 112. Likewise, the second sub-bank gdin latch 324 can latch the gdin bus and provide continued writing of that now-latched din to the second sub-bank 110, freeing the gdin bus for another din for writing to the first sub-bank 110.

In an aspect, the first sub-bank gdin latch 318 and the second sub-bank gdin latch 324 may be implemented as transparent pulse latches. This can provide the previously described benefit of passing the latch input straight to the latch output without a CLK edge. After latching, the transparent pulse latch is in a latched mode, which maintains the latch output state irrespective of state changes on the gdin bus. As also previously described, various techniques for switchable transparency latches are known, and can be adapted to this disclosure by persons of ordinary skill in the art without undue experimentation. Detailed description of their implementation is therefore omitted. In one alternative embodiment, upon reading this disclosure, persons of ordinary skill in the art can implement the first sub-bank gdin latch 318 and the second sub-bank gdin latch 324 with fully clocked, non-transparent multiple bank latches, without undue experimentation.

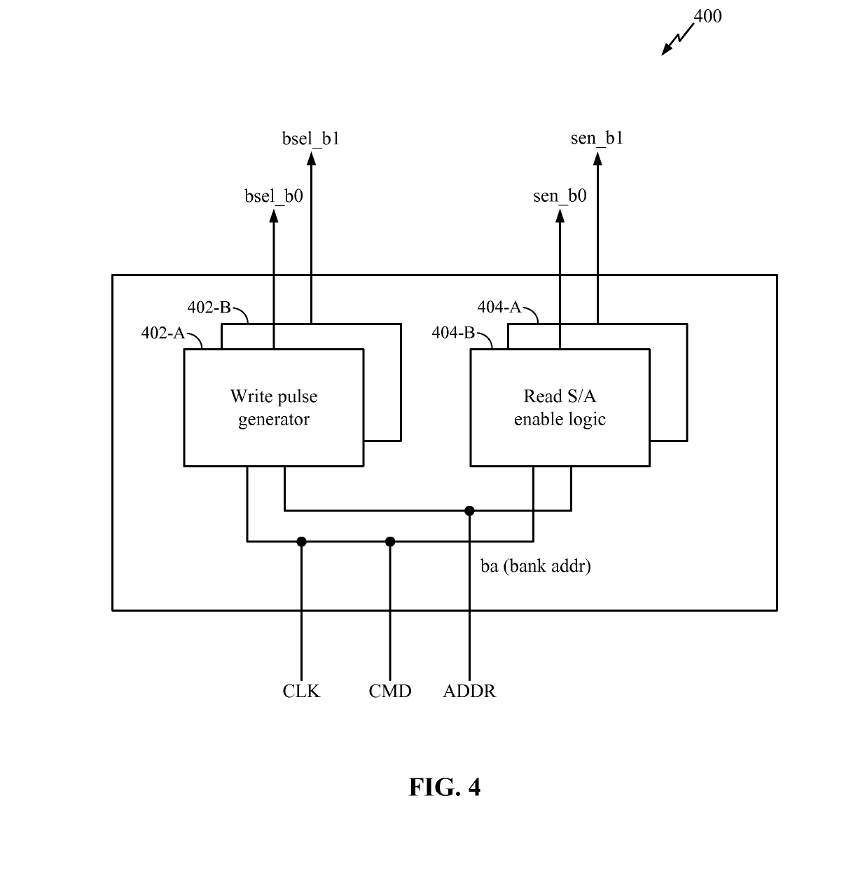

FIG. 4 shows a functional block schematic 400 of one example implementation of the CA control block 310 for the MCA MRAM 300, or other multiple concurrent sub-bank access MRAM devices in accordance with various exemplary embodiments. Example operations and aspects refer to “MCA control block 400,” which means: “circuitry and/or related software modules of computer-executable instructions configured to perform the logical functions including examples shown in the FIG. 4 functional block schematic 400.”

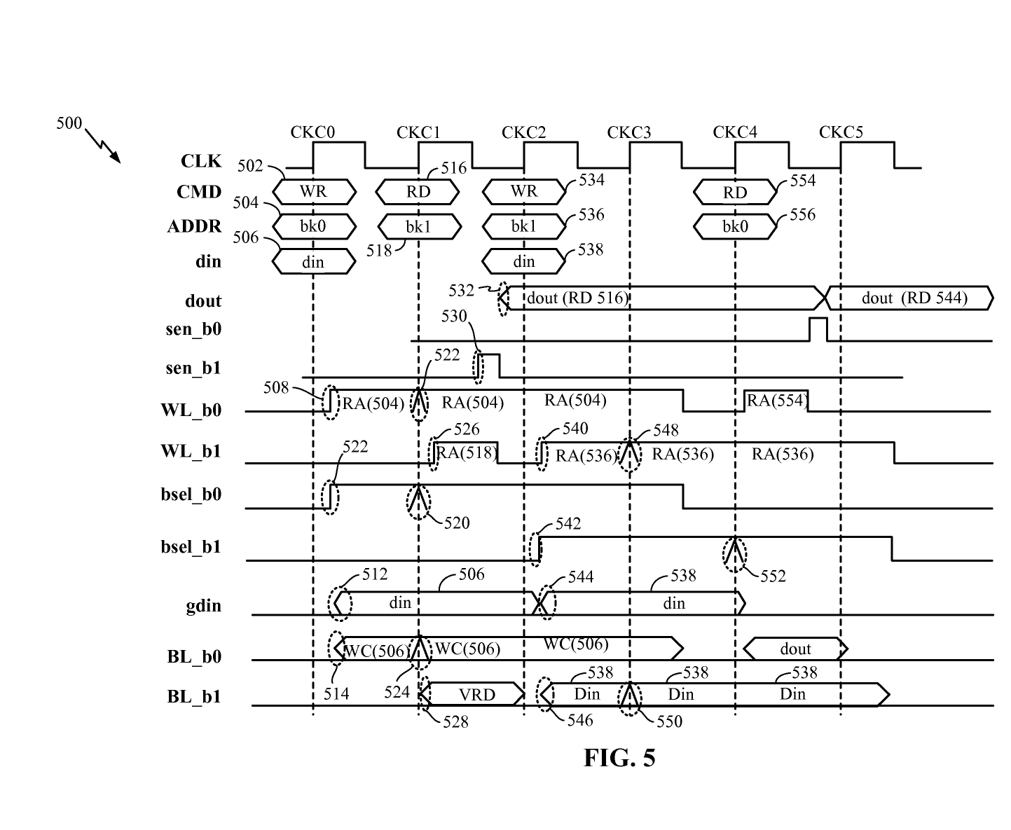

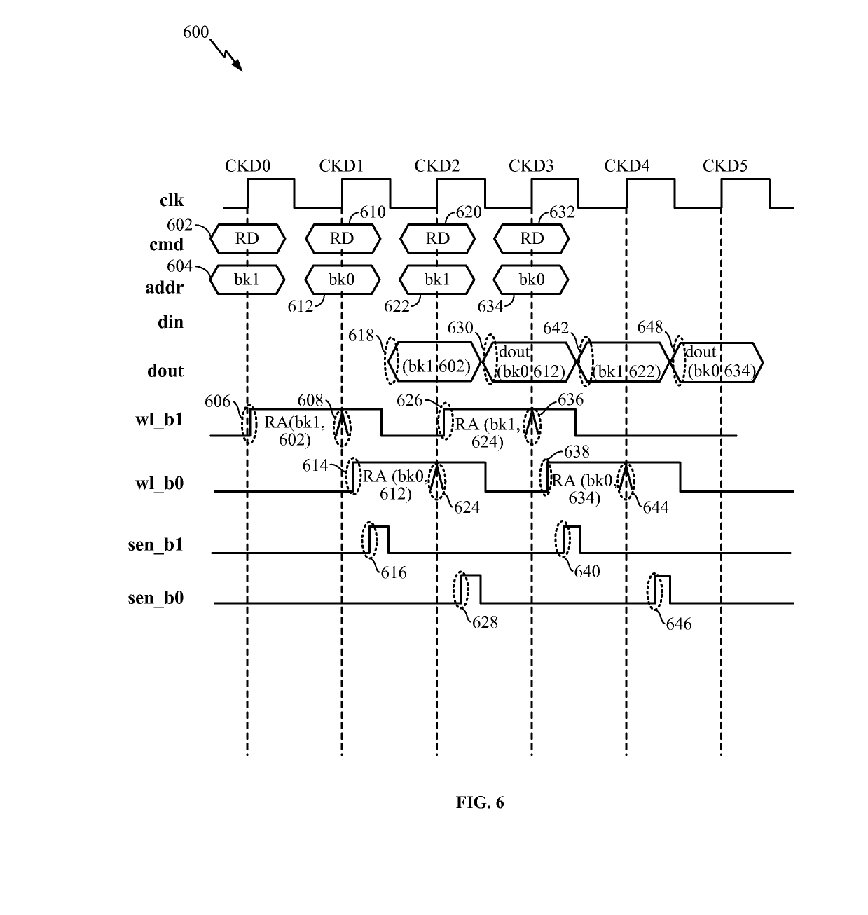

Referring to FIG. 4, the MCA control block 400 may include a first sub-bank write pulse generator 402-A, a second sub-bank write pulse generator 402-B, a first sub-bank read S/A enable logic 404-A, and a second sub-bank read S/A enable logic 404-B. In an aspect, the first sub-bank write pulse generator 402-A may be configured to initiate a write to the first sub-bank 110 in response to a WR CMD, din, and first sub-bank ADDR received at a given CLK edge. Related to this aspect, the first sub-bank write pulse generator 402-A may be configured to generate bsel_b0, and control the first sub-bank gdin latch 322 and the first sub-bank ADDR latch 312 to continue the write to the first sub-bank 110, irrespective of changes to CMD, ADDR or din. In an aspect, the second sub-bank write pulse generator 402-B may be configured in like manner. For example, the first sub-bank pulse generator 402-A may be configured to generate a first sub-bank write latch control (not explicitly visible in the figures) that can be received by the first sub-bank gdin latch 318, and a first sub-bank address latch control that can be received by the first sub-bank ADDR latch 312. For example, the example the second sub-bank pulse generator 402-B may be configured to generate a second sub-bank write latch control (not explicitly visible in the figures) that can be received by the second sub-bank gdin latch 324, and a first sub-bank address latch control that can be received by the second sub-bank ADDR latch 314. Further aspects of the first and second sub-bank write pulse generators 402-A, 402-B, and the first and second bank read S/A enable logic 404-A, 404-B are described in further detail in reference to FIGS. 5 and 6.

Example operations showing read/write while read/write according to one or more exemplary embodiments will be described in reference to the MCA MRAM 300. It will be understood, though, that exemplary embodiments are not limited to the MCA MRAM 300. Read while read operations of methods according to a general embodiment can be performed on other single port memories having a first and a second memory cell array, an address port or combination address/command port, an internal address bus and, for each of the first and second memory cell arrays, an address latch. Example operations of read while read in methods according to one general embodiment may include, receiving an address on the address port and, based on the address, transmitting an internal address that can be received by both a first address latch and a second address latch. The address may be a portion of a read command. A controller can be configured to control a transparency pass through, and latching of the internal address by the first address latch and the second address latch. Assuming, as one example, that the address received on the address port corresponds to a memory cell in the first memory cell array, the controller may control the first address latch, upon receiving the internal address to provide a holding the internal address on the first address latch as a first array address, over a first interval. In an aspect, operations can include accessing the first memory cell array, during the first interval, based on the first array address. In an aspect, operations can include receiving, during the first interval, another address on the address port and, based on the another address, transmitting another internal address. Assuming the another address received on the address port corresponds to a memory cell in the second memory cell array, the controller may control the second address latch, upon receiving the another internal address, to provide a holding the another internal address on the second address latch as a second array address, over a second interval. In methods according to one or more exemplary embodiments, the second interval overlaps the first interval. In an aspect, operations can include accessing the second memory cell array, during the second interval, based on the second array address.

In operations of methods according to one or more exemplary embodiments, in transmitting the internal address may include transmitting the internal address over an address bus to an input of the first address latch. In an aspect, both the first address latch and the second address latch can have their respective inputs coupled to the address bus. However, the control block can control the first address latch and the second address latch such that only one operates to pass through and latch the state of that address bus.

Operations of methods according to one or more exemplary embodiments can further include receiving a clock having a clock period, the clock including a first edge, a second edge and a third edge, in succession, respectively spaced by the clock period. In an aspect receiving the first address may be in association with the first edge and, in a further aspect, a holding of the internal address on the first address latch—as the first array address—can include latching the internal address on an output of the first address latch prior to the second edge. In an aspect, the receiving the second address can be in association with the second edge. In a related aspect, holding the another internal address on the second address latch includes latching the another internal address on an output of the second address latch prior to the third edge.

Referring to FIG. 3, an address, which can be termed a “first read address” for a read operation may be received at the ADDR/CMD port 308 corresponding to a cell in the first sub-bank 110, such as the MC0 cell. One example of transmitting an internal address based on the first read address may be, or may include the CA control block 310 distributing all (or a portion) of the first read address on the CAA bus.

One example of a latching the internal address corresponding to the first read address as a latched first internal address for a first interval may be, or may include, the first sub-bank ADDR latch 312 latching the state of the CAA bus, for an interval determined by the CA control block 310. Further to this example, one example accessing over the first interval a cell in the first memory cell array, based on the latched first internal address, can include the first sub-bank decoder selecting WL_b0 and the first sub-bank R/W BL selector 116 selecting BL_b0. Assuming the accessing is a read, an accessing over the first interval of a cell in the first memory cell array, based on the latched first internal address, can include the CA control block 310 generating sen_b0 for the first sub-bank read/write enable drivers 130 to enable the first sub-bank S/A 126. The read of MC0 is then output from the read data from the data out port 306. Another example of accessing a cell in the first memory cell array over the first interval can include driving a write current through MC0. This can be provided by the CA control block 310 controlling the first bank gdin latch 318 to capture a data in received through the data in bus 304, and generating bsel_b0 to enable the first sub-bank SE write driver S/A 126, combined with the write multiplexor of the first sub-bank R/W BL selector 116 selecting the BL_b0.

The above-described examples according to various exemplary embodiment include features of latching the internal access address, i.e., an address prior to decoding to the word line and bit line of the addressed resistive memory cell. One example alternative embodiment (not explicitly visible in the figures) is to latch the word line and the bit line. Referring to FIG. 3, one example implementation can include placing a word line latch (not explicitly visible in the figures) on the output of the first sub-bank decoder 114 and, similarly, placing another word line latch (not explicitly visible in the figures) on the output of the second sub-bank decoder 118 and (not explicitly visible in the figures). In an aspect, one example implementation according to the example alternative embodiment can place a bit line latch (not explicitly visible in the figures) in the first sub-bank R/W BL selector 116, and another bit line latch (not explicitly visible in the figures) in the second sub-bank R/W BL selector 120.

It will be appreciated that circuitry according to example implementation above can be one implementation of one general example. The general example can comprise a first array of resistive memory cells having a plurality of first array word lines and a plurality of first array bit lines, and resistive memory cells associated with intersections of the first array word lines and first array bit lines. The first sub-bank latching access circuitry can comprise a first array row decoder configured to receive a row field of the internal address and, in response to a value of the row field, select a corresponding one of the first array word lines. The first array word line latch can be configured to latch the corresponding one of the first array word lines at an enabled state over the first interval. A first array bit line selector can be configured to receive a bit field of the internal address and, in response to a value of the bit field, select a corresponding one of the first array bit line. A first array bit line latch can be configured to latch the corresponding one of the first array bit lines at an enabled state over the first interval.

FIG. 5 shows one simulated timing diagram 500 (hereinafter “timing diagram 500) of example read-while-write and write-while-write access of the MCA MRAM 300 in accordance with various exemplary embodiments. Example operations will be described that include receiving a clock having a clock period, the clock including a succession of a first edge, a second edge and a third edge, respectively spaced by the clock period. A latching the first array address may be in association with the first edge. Accessing the cell in the first memory cell array can be a reading the cell in the first memory cell array, such that the first interval is a first read interval. Examples include the first read interval extending past the second edge. Examples further include reading the second memory cell array, and identifying a second array address, based at least in part on the second address, and latching the second array address, in association with the second edge. In an example, the latching maintains the latched second array address for a second read interval that extends past the third edge, and during the second read interval a reading a cell in the second memory cell array may be performed, based on the latched second array address.

Referring to FIG. 5, the timing diagram 500 shows the access operations relative to a sequence of six edges of CLK, labeled “CKC0, CKC1 . . . CKC5.” It will be understood that six edges is an arbitrary quantity, selected to illustrate aspects, and does not limit the scope of any exemplary embodiment. The timing diagram 500 and example operations referencing are described assuming that latch operations result from the rising edges of CKC0, CKC1 . . . CKC5. This is only for purposes of example, and is not intended to limit the scope of any of the exemplary embodiments or aspects thereof. In addition, persons of ordinary skill, upon reading this disclosure, can readily adapt the description to alternative implementations that latch on the falling edges. For convenience, the rising edge of CKC0 will be alternatively referred to as a “first edge CKC0.” Likewise, the rising edges of CKC1, CKC2 . . . CKC5 will alternatively referred to as the second edge CKC1, third edge CKC2, fourth edge CKC3, fifth edge CKC4 and sixth edge CKC5.

Example operations relative to the timing diagram 500 are described assuming the first sub-bank ADDR latch 312, the second sub-bank ADDR latch 314, the first bank gdin latch 318, and the second gdin latch 324 (collectively, “concurrent access latches”) are transparent pulse latches. Accordingly, the timing diagram 500 assumes latch inputs can pass through to latch outputs without a CLK edge. The timing diagram also assumes conventional transparent pulse latch operation of latching the input state on a transition from the transparent mode to latched mode, where a change on the latch input will not change the latch output. It will be understood that description assuming transparent pulse latches is not intended to, and does not limit the scope of any exemplary embodiments. For example, upon reading this disclosure, persons of ordinary skill in the art can adapt the timing diagram 500 and example operations to implementations with fully clocked, non-transparent concurrent access latches, without undue experimentation.

The timing diagram 500 assumes the CA control block 310 is implemented by the FIG. 4 MCA control block 400, configured to separately generate bsel_b0 and bsel_b1, and separately generate sen_b0 and sen_b1, for driving by the first sub-bank read/write enable drivers 130 and second sub-bank read/write enable drivers 132.

To illustrate certain aspects, the timing diagram 500 assumes the MCA MRAM 300 is configured and fabricated to have a one CLK read latency. This is only for illustration, and is not intended as limiting the scope of any exemplary embodiments of aspects of the same. On the contrary, examples of read-while-read access on an MCA MRAM implementation having a two CLK read latency are described in reference to FIG. 6.

Referring to FIG. 5, at a time (shown but not separately labeled) preceding the first edge CKC0 sufficient to meet set-up requirements, a WR 502 and write address value bk0 504 are received at the ADDR/CMD port 308, and a din 506 is received at the data-in port 304 of the GIN/GOUT data interface buffer 302. In response, the CA control block 310 distributes (not explicitly visible in FIG. 5) on the CAA bus an internal address, which can be assumed, for purposes of example, to be a repeat of the write address bk0 504. It will be understood that this not intended to limit the scope of any exemplary embodiments. For example, in various alternative embodiments the CA control block 310 may perform partial decoding of the write address bk0 504 that may be reflected in the internal address distributed on the CAA bus.

Referring to FIGS. 3 and 5, in an aspect the CA control block 310 can be configured, in response to WR 502 and bk0 504 to switch both the first sub-bank ADDR latch 312 and the first bank din latch 318 to a transparent mode. The first sub-bank ADDR latch 312, being in transparent mode, immediately transmits the row or word line field of bk0 504 to the first sub-bank decoder 114, and the column or bit line field of bk0 504 to the first sub-bank R/W BL selector 116. The first sub-bank decoder 114, in turn, enables at 508 the WL_b0 word line to MC0. FIG. 5 labels the WL_b0 value enabled at 508 as “RA (504).” Concurrently, the write multiplexer of the first sub-bank R/W BL selector 116 couples the output of the first sub-bank SE write driver 316 to the bit line, BL_b0 of the MC0 cell. It may be assumed that the latency of the write multiplexer of the first sub-bank R/W BL selector 116 is not significant and, therefore, it is omitted from FIG. 5. The CA control block 310, in response to the combination of bk0 504 and WR 502, generates, at 510, bsel_b0, which enables the write driver enabling logic 320 in the first sub-bank latching write driver 316. At 512, the gdin voltage corresponding to din 506 is established at the input of the first bank gdin latch 318 of the first sub-bank latching write driver 316. Since the first bank gdin latch 318 is in a transparent state and the first sub-bank latching write driver 316 is connected, as described above, to the bit line for MC0, at 514, shortly after 512, a write current corresponding to din 506 is passed through BL_b0 and through MC0. FIG. 5 labels this current on BL_b0 as “WC (506).”

In an aspect, starting at some logic delay after the second edge CKC1, while the WR 502 write process to MC0 in the first sub-bank 110 is in progress, a read access of the second sub-bank 112 may be performed. One example according to this “read-while write” aspect will now be described.

At a time preceding the second edge CKC1 to meet set-up requirements, and while BL_b0 is maintaining WC(506) through MC0 as described above, a RD (read command) 516 with second sub-block address bk1 518 may be received at the ADDR/CMD port 308.

In an aspect, the CA control block 310 may be configured to respond to this reception at the second edge CKC1 by: i) continuing, at 520, to generate bsel_b0 at the value corresponding to WR 502; and ii) controlling the first sub-bank ADDR latch 312 to latch RA(504) and the first bank gdin latch 318 to latch din 506. Referring to the timing diagram 500, controlling the first sub-bank ADDR latch 312 to latch RA (504) is shown as 522. Controlling the first bank gdin latch 318 to latch din 506 is reflected by the event 524 of the BL_b0 line continuing to carry the write current WC (506). In an aspect, the first sub-bank ADDR latch 312 and first bank gdin latch 318 may be configured, or controlled, or both, to be non-transparent after the above-described latching operations until a release (not explicitly visible in FIG. 3, 4, or 5), for example, at a termination of the write process corresponding to WR 502. Referring to FIGS. 4 and 5, the continuing at 520 to generate bsel_b0 at the value to continue the writing of MC0 can be provided by configuring the first sub-bank write pulse generator 402-A as separate logic. Configured as such, the first sub-bank write pulse generator 402-A can continue the WR 502 to bk0 504 (MC0) until the write is complete.

Continuing with description of example accesses, in response to the RD 516 and corresponding bk1 518, the CA control block 310 can pass to the CAA bus the internal address it generates in response to bk1 518. As previously described, in one example, the internal address can be the entire bk1 518. Both the first sub-bank ADDR latch 312 and the second sub-bank ADDR latch 314 receive the CAA bus but, in an aspect, the CA control block 310 maintains the latched state of the first sub-bank ADDR latch 312 and switches the second sub-bank ADDR latch 314 to a transparent state. The second sub-bank ADDR latch 314, being transparent (or in a transparent mode), passes the row or word line field of bk1 518 to the second sub-bank decoder 118. The second sub-bank decoder 118, in turn, enables at 526 the WL_b1 word line to MC1. FIG. 5 labels the WL_b1 value enabled at 526 as “RA (518).” The transparent second sub-bank ADDR latch 314 passes the column or bit line field of bk1 518 to the second sub-bank R/W BL selector 120. In response, the read multiplexer of the second sub-bank R/W BL selector 120 connects the bit line, BL_b1, of MC1 to the input of the second sub-bank S/A 128. Concurrently, the CA control block 310, or other logic (not explicitly visible in FIG. 3, 4, or 5) can pass a read current through BL_b1 to establish, at 528, a voltage “VRD” on BL_b1 corresponding to the magnetization state of MC1. At time 530, when VRD is sufficiently stead-state, the CA control block 310 generates, or causes the second sub-bank read/write enable logic 132 to generate sen_b1, which can be a pulse. The generated sen_b1 enables the second sub-bank S/A 124 to output “dout (RD 516)” from the data-out port 306. Referring to FIG. 4, the second sub-bank read S/A enable logic 404-B may generate, or cause the second sub-bank read/write enable logic 132 to generate, sen_b1 at 530. After the pulse of sen_b1, the second sub-bank S/A goes to a disabled output state.

As previously described, the timing diagram 500 assumes the MCA MRAM 300 is configured and fabricated to have a one CLK read latency. Therefore, at CKC2, one CLK edge after the second edge CKC1, the dout (RD 516) result of the RD 516 read of MC1 is output from the data-out port 306.

In an aspect, starting at CKC2, while the WR 502 write process to MC0 in the first sub-bank 110 remains in progress, write access of the second sub-bank 112 may also be performed. One example according to this “write-while write” aspect will now be described. It will be understood that the write-while-write may have commenced at the second edge CKC1 but, for this example, the above-described read while-write—initiated by RD 516—was performed.

Referring to FIG. 5, at a time (shown but not separately labeled) preceding the third edge CKC2 sufficient to meet set-up requirements, a WR 534 and write address value bk1 536 are received at the ADDR/CMD port 308, and a din 538 is received at the data-in port 304 of the GIN/GOUT data interface buffer 302. The CA control block 310, in response, may forward or distribute on the CAA bus an internal address corresponding to bk1 536. The first sub-bank ADDR latch 312 and the second sub-bank ADDR latch 314 both receive the CAA bus but, in an aspect, the CA control block 510 is configured to switch only the second sub-bank ADDR latch 314 to a transparent state. Further to this aspect, the first sub-bank ADDR latch 312 may be controlled, for example, to maintain a present latched state. The second sub-bank ADDR latch 314, being transparent (or in a transparent mode), passes the row or word line field of the internal address corresponding to bk1 536 to the second sub-bank decoder 118. The second sub-bank decoder 118, in turn, enables at 540 the WL_b1 word line to MC1, as is labeled “RA (536).”

Concurrent, or approximately concurrent with the enabling at 540 of the AL_b1 line, the write multiplexer of the second sub-bank R/W BL selector 120 couples the output of the second sub-bank latching write driver 322 to the bit line, BL_b1 of the MC1 cell. It may be assumed that the latency of the write multiplexer of the second sub-bank R/W BL selector 120 is not significant and, therefore, it is omitted from FIG. 5. The CA control block 310, in response to the combination of bk1 536 and WR 534, generates, at 542, bsel_b1 at a value enabling the write driver enabling logic 326 in the second sub-bank latching write driver 322. At 544, the gdin voltage corresponding to din 538 is established at the input of the second gdin latch 324 of the second sub-bank latching write driver 322. Since the second gdin latch 324 is in a transparent state and the second sub-bank latching write driver 322 is connected to the bit line for MC1, at 546, shortly after 544, a write current corresponding to din 538 is passed through BL_b1 and through MC1. FIG. 5 labels this current on BL_b0 as “WC (528).”

The above-described write-while-write may render both the first sub-bank 110 and the second sub-bank 112 not accessible for an interval. It will be understood that this not a limit of the exemplary embodiments and, instead, is an implementation-specific limitation due to the example quantity of sub-banks, namely two, being less than the example write latency of three. Persons of ordinary skill in the art, upon reading this disclosure in its entirety, can readily implement a four sub-bank variation of the MCA MRAM 300, in accordance with various exemplary embodiments, without undue experimentation.

Referring again to FIG. 5 the above-described write-while-write is still ongoing at the fourth edge CKC3 and therefore prevents starting another access at the fourth edge CKC3. However, in an aspect, at the fourth edge CKC3 the second sub-bank ADDR latch 314, the second gdin latch 324 and the CA control block 310 may be operated to continue the WR 534 started at the third edge CKC2. This can allow access of the first sub-bank 110 at the next, i.e., fifth edge, CKC4. Illustrative of this aspect, at the fourth edge CKC3 the second sub-bank ADDR latch 314 may at 548 latch the internal address distributed on the CAA bus by the CA control block 310 in response to bk1 536 and, at 550 the second gdin latch 324 may latch the din 538. In addition, the CA control block 310 may be configured to maintain, at 552, bsel_b1 at the value corresponding to WR 534. This allows, at the fifth edge CKC4, an access of the first sub-bank 110, for example, the read defined by RD 554 and its read address bk0 556 to be received while continuing the WR 534 write to the second sub-bank 112. Example operations (not separately visible on FIG. 5) for the read defined by RD 554, may be substantially as described for the access RD 518, with labeling changed to the MCA MRAM 300 logical blocks associated with the first sub-bank 110.

As illustrated by the examples described in reference to FIGS. 3, 4 and 5, exemplary embodiments provide a method for concurrent read/write of a memory having a first memory cell array and a second memory cell array that share a single data in port and single data out port. FIG. 3 shows one example of such structure. In an aspect, operations of example methods can include receiving a clock, having a first edge, a second edge and a third edge, spaced apart by a clock period and receiving, in association with the first edge, a command at an command/address port to access a memory cell in the first memory cell array. In response to the command to access a memory cell in the first memory cell array, the memory cell is accessed over a first interval. The first interval can begin at a device delay after the first edge, which is prior to the second edge, and extend past the second edge. Operations of example methods can include, in an aspect, in association with the second edge, receiving a command at the command/address port to access a memory cell in the second memory cell array. Operations of example methods can also include, in an aspect, in response to the command to access a memory cell in the second memory cell array, accessing that memory cell over a second interval. In accordance with various exemplary embodiments, the second interval overlaps the first interval. In an aspect, associated with the first edge can be a receiving a data in, and the command to access a memory cell in the first memory cell array can include a command to write the data in to the memory cell in the first memory cell array. In a further aspect, operations of example methods can further include writing the data in to the memory cell over the first interval. In accordance with the further aspect, the first interval can be a write interval, and the write interval can extend past the third edge.

In an aspect, operations of example methods according to one or more exemplary embodiments, the clock further can include a fourth edge spaced one clock period after the third edge. In a further aspect, operations in example methods can include receiving, in association with the third edge, another data in and a command to write the another data in to a memory cell in the second memory cell array. Operations in example methods can include, in response to the command to write the another data in to a memory cell in the second memory cell array, writing the another data in to said memory cell over a third interval, wherein the third interval overlaps the first interval by more than one clock period.

FIG. 6 shows one simulated timing diagram 600 (hereinafter “timing diagram 600”), relative to a sequence of six CLK edges labeled, respectively, “CLKD0, CLKD1 . . . CLKD5,” of example read-while-read access on one example multiple concurrent sub-bank access MRAM in accordance with various exemplary embodiments. To illustrate benefits, the timing diagram 600 assumes MCA MRAM 300 is configured and/or fabricated to meet a slower, e.g., two-CLK read latency. As will be apparent from the description, among other features and benefits provided by the read-while-read aspect of the MCA MRAM 300 according to various exemplary embodiments is a net read access rate of one read per CLK cycle, even though the individual sub-banks have a two-CLK read latency. To avoid description of details not pertinent to concepts, the read operations will, like the previous examples, assume bk0 corresponds to the first sub-bank 110 MRAM cell MC0 and bk1 corresponding to the second sub-bank 112 MRAM cell MC1. Description of the timing diagram 600 and example operations referencing the same, arbitrarily assume at latching operations result from the rising edges of CKD0, CKD1 . . . CKD5. This is only for purposes of example, and is not intended to limit the scope of any of the exemplary embodiments or aspects thereof. Persons of ordinary skill, upon reading this disclosure, can readily adapt the description to alternative implementations that latch on the falling edges. For convenience in referencing the timing diagram 500, the rising edge of CKD0 will be alternatively referred to as a “first edge CKD0.” Likewise, the rising edges of CKD1, CKS2 . . . CKC5 will alternatively referred to as the second edge CKD1, third edge CKD2, fourth edge CKD3, fifth edge CKD4 and sixth edge CKD5.

Referring to FIG. 6, at a time (shown but not separately labeled) preceding the first edge CKD0 to meet set-up requirements, an RD 602 and corresponding read address, labeled as bk1 604″ are received at the ADDR/CMD port 308. In response to the RD 602 and corresponding bk1 604, the CA control block 310 can distribute on the CAA bus an internal address corresponding to bk1 604, and control the second sub-bank ADDR latch 314 to switch to a transparent state. The first sub-bank ADDR latch 312 also receives the CAA bus, but may be controlled by the CA control block 310 to maintain a previously latched state. The second sub-bank ADDR latch 314, being transparent (or in a transparent mode), passes a row or word line field of bk1 604 to the second sub-bank decoder 118. The second sub-bank decoder 118, in turn, enables at 606 the WL_b1 word line to MC1, as shown by the label as “RA (bk1, 602).” Concurrent, or approximately concurrent with the enabling at 606 of the WL_b1 line, the read multiplexer of the second sub-bank R/W BL selector 120 couples the bit line BL_b1 of MC1 to the input of the second sub-bank S/A 128. It may be assumed that the latency of the read multiplexer of the second sub-bank R/W BL selector 120 is not significant and, therefore, it is omitted from FIG. 6. Concurrently, the CA control block 310, or other logic (not explicitly visible in FIG. 3, 4 or 6) can pass a read current through BL_b1 to establish, at 528, a voltage (not explicitly visible on FIG. 6) on BL_b1 corresponding to the state of MC1.

As previously described, the timing diagram 600 assumes MCA MRAM 300 is configured and/or fabricated to meet a slower, e.g., two-CLK read latency. Accordingly, it is assumed that at CKD1 the voltage (not explicitly visible on FIG. 6) on BL_b1 corresponding to the state of MC1 may not be sufficiently settled at the input of the second sub-bank S/A 124 to generate sen_b1. Instead, in an aspect, the CA control block 310 controls second sub-bank ADDR latch 314 to latch the internal address on the CAA bus corresponding to bk1 604 at the second edge CKD1 and continue the read of MC1. This latching enables the MCA MRAM 300 to perform a read-while-read, by receiving at the ADDR/CMD port 308, at the second edge CKD1, a RD 610 and corresponding read address bk0 612 to read MCO in the first sub-bank 110.

In response to the RD 610 and corresponding bk0 612, the CA control block 310 can distribute on the CAA bus an internal address corresponding to bk0 612 and switch the first sub-bank ADDR latch 312 to a transparent mode. The first sub-bank ADDR latch 312 therefore passes to the input of the first sub-bank decoder 114 the row or word line field of the internal address corresponding to bk0 612. The second sub-bank ADDR latch 314, though, is maintained at 608 in its latched state holding the CAA bus address corresponding to bk1 604. The first sub-bank decoder 114, in turn, enables at 614 the WL_b0 word line to MC0, as shown by the label as “RA (bk0, 612).” Concurrent with the first sub-bank ADDR latch 312 passing the row or word line field of the internal address corresponding to bk0 612 to the first sub-bank decoder, the first sub-bank ADDR latch 312 passes the column or bit line field of the internal address corresponding to bk0 612 to the first sub-bank R/W BL selector 116. In response, the read multiplexer of the first sub-bank R/W BL selector 116 connects the MC0 bit line, BL_b0, to the input of the first sub-bank S/A 122. As described for the read corresponding to RD 602, a read current may pass through BL_b0 to establish voltage (not explicitly visible on FIG. 6) on BL_b0 corresponding to the state of MC0.

At 616, the CA control block 310 generates sen_b1, which enables the second bank S/A 124, causing at 618 the read result dout (bk1, 604) to output from the data-out port 306.

At a time (shown but not separately labeled) preceding the third edge CKD2 to meet set-up, an RD 620 and corresponding read address bk1 622 are received at the ADDR/CMD port 308. In response to the RD 620 and corresponding bk1 622, the CA control block 310 can distribute on the CAA bus an internal address corresponding to bk1 622 and switch the second sub-bank ADDR latch 314 to a transparent mode. The second sub-bank ADDR latch 314 therefore passes to the input of the second sub-bank decoder 118 the row or word line field of the internal address corresponding to bk1 622. The first sub-bank ADDR latch 312, though, is maintained at 624 in its latched state holding the CAA bus address corresponding to bk0 612. The second sub-bank decoder 118, in turn, enables at 626 the WL_b1 word line to MC1, as shown by the label as “RA (bk1, 612).” Concurrent with the second sub-bank ADDR latch 314 passing the row or word line field of the internal address corresponding to bk1 622 to the second sub-bank decoder 118, the second sub-bank ADDR latch 314 passes the column or bit line field of the internal address corresponding to bk1 622 to the second sub-bank R/W BL selector 120. In response, the read multiplexer of the second sub-bank R/W BL selector 120 connects the MC1 bit line, BL_b1, to the input of the second sub-bank S/A 128. As described for the read corresponding to RD 602, a read current may pass through BL_b1 to establish voltage (not explicitly visible on FIG. 6) on BL_b1 corresponding to the state of MC1.

At 628, the CA control block 310 generates sen_b0, which enables the first sub-bank S/A 122, causing at 630 the read result dout (bk0, 612) to output from the data-out port 306.

At a time (shown but not separately labeled) preceding the fourth edge CKD3 to meet set-up, an RD 632 and corresponding read address bk0 634 are received at the ADDR/CMD port 308. At CKD3, the CA control block 310 controls the first sub-bank ADDR latch 312 to latch, at 636, the RA (bk1, 622) and continue the read of MC1. In response to the RD 632 and corresponding bk0 634, the CA control block 310 can distribute on the CAA bus an internal address corresponding to bk0 634 and switch the first sub-bank ADDR latch 312 to a transparent mode. The first sub-bank ADDR latch 312 therefore passes to the input of the first sub-bank decoder 112 the row or word line field of the internal address corresponding to bk0 634. The second sub-bank ADDR latch 314, though, is latched at 636 to hold on its output the CAA bus address corresponding to bk1 622. The first sub-bank decoder 114, in response to receiving the row or word line field of the internal address corresponding to bk0 634, enables at 638 the WL_b0 word line to MC0, as shown by the label as “RA (bk0, 634).” Concurrent with the first sub-bank ADDR latch 312 passing the row or word line field of the internal address corresponding to bk0 634 to the first sub-bank decoder 114, the first sub-bank ADDR latch 312 passes the column or bit line field of the internal address corresponding to bk0 634 to the first sub-bank R/W BL selector 116. In response, the read multiplexer of the first sub-bank R/W BL selector 116 connects the MC0 bit line, BL_b0, to the input of the first sub-bank S/A 126. As described for the read corresponding to RD 610, a read current may pass through BL_b0 to establish voltage (not explicitly visible on FIG. 6) on BL_b0 corresponding to the state of MC0.

At 640, the CA control block 310 generates sen_b1, which enables the second bank S/A 124, causing at 642 the read result dout (bk1, 622) to output from the data-out port 306.

Referring to FIG. 6, the timing diagram 600 assumes no accesses received at the fifth edge CKD4 and the sixth edgeCKD5. In an aspect, irrespective of no new access being received at the fifth edge CKD4, the CA control block 310 may control the first sub-bank ADDR latch 312 to latch, at 644, the RA (row address) of bk0 634 to continue the read of MC0 in the first sub-bank 110. At 646, the CA control block 310 generates sen_b0, which enables the first bank S/A 122, causing at 648 the read result dout (bk0, 634) to output from the data-out port 306.

Referring to FIG. 3, since the data-out port 306 is the data output port, the described read accesses can enable only one among the first sub-bank S/A 126 and second sub-bank S/A 128. A result may be under-utilization of the first sub-bank S/A 126 and second sub-bank S/A 128. The under-utilization may incur costs, for example, in IC chip area.

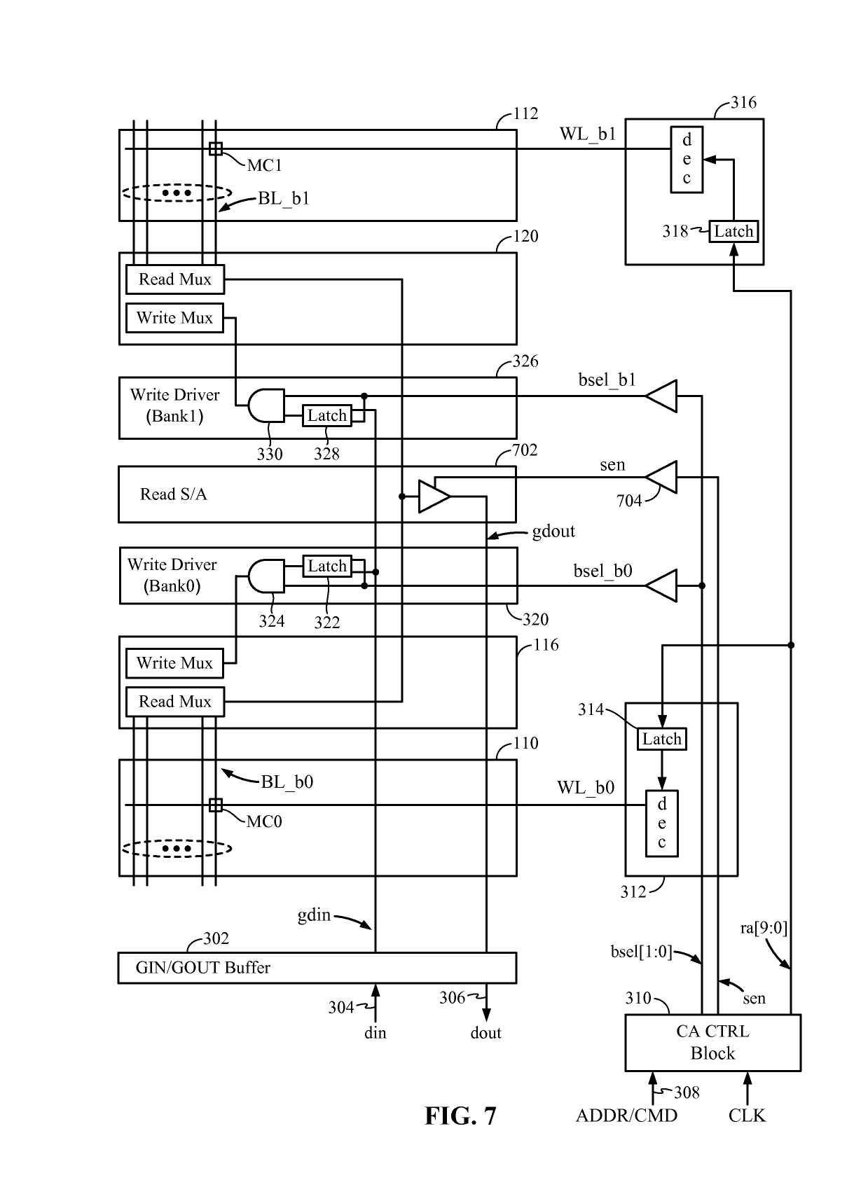

FIG. 7 shows a functional block schematic 700 of one example multiple concurrent sub-bank access MRAM, which may reduce the above-described under-utilization by using a shared S/A 702 in place of the separate first sub-bank S/A 128 and second sub-bank S/A 128.

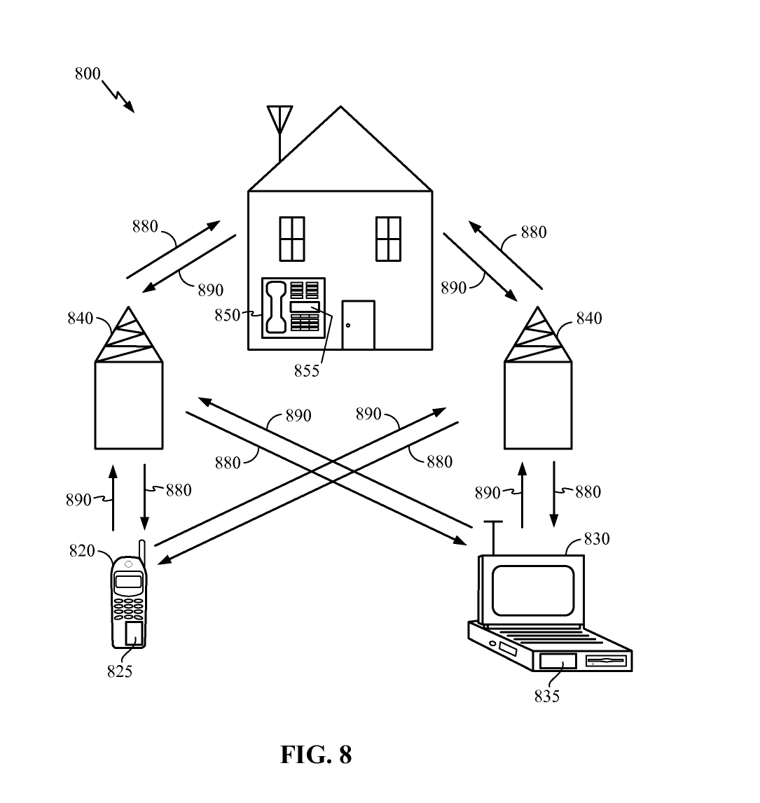

FIG. 8 illustrates an exemplary wireless communication system 800 in which one or more embodiments of the disclosure may be advantageously employed. For purposes of illustration, FIG. 8 shows three remote units 820, 830, and 850 and two base stations 840. It will be recognized that conventional wireless communication systems may have many more remote units and base stations. The remote units 820, 830, and 850 include integrated circuit or other semiconductor devices 825, 835 and 855 (including on-chip voltage regulators, as disclosed herein), which are among embodiments of the disclosure as discussed further below. FIG. 8 shows forward link signals 880 from the base stations 840 and the remote units 820, 830, and 850 and reverse link signals 890 from the remote units 820, 830, and 850 to the base stations 840.

In FIG. 8, the remote unit 820 is shown as a mobile telephone, the remote unit 830 is shown as a portable computer, and the remote unit 850 is shown as a fixed location remote unit in a wireless local loop system. For example, the remote units may be any one or combination of a mobile phone, hand-held personal communication system (PCS) unit, portable data unit such as a personal data assistant (PDA), navigation device (such as GPS enabled devices), set top box, music player, video player, entertainment unit, fixed location data unit such as meter reading equipment, or any other device that stores or retrieves data or computer instructions, or any combination thereof. Although FIG. 8 illustrates remote units according to the teachings of the disclosure, the disclosure is not limited to these exemplary illustrated units. Embodiments of the disclosure may be suitably employed in any device that includes active integrated circuitry including memory and on-chip circuitry for test and characterization.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an embodiment of the invention can include a computer readable media embodying a method for implementation. Accordingly, the invention is not limited to illustrated examples and any means for performing the functionality described herein are included in embodiments of the invention.

The foregoing disclosed devices and functionalities may be designed and configured into computer files (e.g., RTL, GDSII, GERBER, etc.) stored on computer readable media. Some or all such files may be provided to fabrication handlers who fabricate devices based on such files. Resulting products include semiconductor wafers that are then cut into semiconductor die and packaged into a semiconductor chip. The chips are then employed in devices described above.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A method for read/write of a memory having a first memory cell array, a second memory cell array, a data in port, a data out port, and a command/address port, comprising:
receiving a clock, wherein the clock includes a first edge, a second edge and a third edge, spaced apart by a clock period
receiving, in association with the first edge, a command at the command/address port to access a memory cell in the first memory cell array;
in response to the command to access a memory cell in the first memory cell array, accessing the memory cell over a first interval, wherein the first interval begins prior to the second edge and extends past the second edge;
receiving, in association with the second edge, a command at the command/address port to access a memory cell in the second memory cell array; and
in response to the command to access a memory cell in the second memory cell array, accessing said memory cell over a second interval, wherein the second interval overlaps the first interval.

2. The method of claim 1, further comprising, in association with the first edge, receiving a data in, wherein the command to access a memory cell in the first memory cell array includes a command to write the data in to the memory cell in the first memory cell array, and wherein the method further comprises writing the data in to the memory cell over the first interval, wherein the first interval is a write interval, and wherein the write interval extends past the third edge.

3. The method of claim 2, wherein the clock further includes a fourth edge spaced one clock period after the third edge, wherein the method further comprises:
receiving, in association with the third edge, another data in and a command to write the another data in to a memory cell in the second memory cell array; and
in response to the command to write the another data in to a memory cell in the second memory cell array, writing the another data in to said memory cell over a third interval, wherein the third interval overlaps the first interval by more than one clock period.

4. A method for read/write of a memory having a first memory cell array, a second memory cell array, a data in port, a data out port, and an address port, comprising
receiving an address on the address port and, based on the address, transmitting an internal address;
receiving the internal address by a first address latch and holding the internal address on the first address latch as a first array address, over a first interval;
accessing the first memory cell array, during the first interval, based on the first array address;
receiving another address on the address port and, based on the another address, transmitting another internal address;
receiving the another internal address by a second address latch and holding the another internal address on the second address latch as a second array address, over a second interval, wherein the second interval overlaps the first interval; and
accessing the second memory cell array, during the second interval, based on the second array address.

5. The method of claim 4, wherein transmitting the internal address comprises transmitting the internal address over an address bus to an input of the first address latch, and wherein transmitting the another internal address comprises transmitting the another internal address over the address bus to an input of the second address latch.

6. The method of claim 4, further comprising receiving a clock having a clock period, the clock including a first edge, a second edge and a third edge, in succession, respectively spaced by the clock period,
wherein the receiving the first address is in association with the first edge,
wherein holding the internal address on the first address latch includes latching the internal address on an output of the first address latch prior to the second edge,
wherein the receiving the second address is in association with the second edge, and
wherein holding the another internal address on the second address latch includes latching the another internal address on an output of the second address latch prior to the third edge.

7. The method of claim 6,
wherein holding the internal address on the first address latch further includes switching the first address latch to a transparent mode that passes the internal address to the output of the first address latch, followed by said latching the internal address, and
wherein holding the another internal address on the second address latch further includes switching the second address latch to a transparent mode that passes the another internal address to the output of the second address latch, followed by said latching the another internal address.

8. The method of claim 7, wherein accessing the first memory cell array comprises reading a cell in the first memory cell array, and wherein the first interval is a first read interval that extends past the second edge, wherein reading the cell in the first memory cell array comprises:
prior to the first edge switching a first sense amplifier to a disabled output state;
over the first read interval forming a voltage on an input of the first sense amplifier corresponding to the cell in the first memory cell array; and
after the second edge and prior to the third edge, switching the first sense amplifier to an enabled state, communicating the output of the first sense amplifier through the data out port and switching the first sense amplifier back to the disabled output state.

9. The method of claim 8, wherein the clock further includes a fourth edge following the third edge by the clock period, wherein accessing the second memory cell array comprises reading a cell in the second memory cell array, and the second interval is a second read interval, and wherein reading the cell in the second memory cell array comprises:
prior to the second edge switching a second sense amplifier to a disabled output state;
over the second read interval forming a voltage on an input of the second sense amplifier corresponding to the cell in the second memory cell array; and
after the third edge and prior to the fourth edge, enabling the second sense amplifier to output to the data out port, and returning the second sense amplifier back to the disabled output state.

10. The method of claim 6, wherein accessing the first memory cell array comprises writing a data to a cell in the first memory cell array, wherein the first interval is a first write interval that extends past the third edge, and wherein writing the data to the cell in the first memory cell array comprises:
associated with the first edge, receiving the data at the data in port;
latching the data as a latched write data, prior to the second edge, until a termination of the first write interval;
driving a write current through the cell in the first memory cell array, in a direction corresponding to a value of the latched write data.

11. The method of claim 10, wherein accessing the second memory cell array comprises reading a cell in the first memory cell array, and wherein the second interval is a read interval that terminates prior to the third edge.

12. The method of claim 11, wherein reading the cell in the second memory cell array comprises:
prior to the second edge switching a sense amplifier to a disabled output state;
over the read interval forming a voltage on an input of the sense amplifier corresponding to the cell in the second memory cell array; and
after the second edge and prior to the third edge, enabling the sense amplifier to output to the data out port and returning the sense amplifier back to the disabled output state.

13. The method of claim 12, wherein the clock further includes, following the third edge, a fourth edge, a fifth edge and a sixth edge in succession, respectively spaced by the clock period,
wherein the data is a first data and the write interval is a first write interval,
wherein the address is a first address, the another address is a second address, the internal address is a first internal address, and the another internal address is a second internal address, and wherein the method further comprises:
associated with the third edge, receiving a third address on the address port and a second data on the data in port and, based on the third address, transmitting a third internal address;
receiving the third internal address by the second address latch and holding the third internal address on the second address latch as another second array address, over a second write interval;
latching the second data as a latched second write data, prior to the fourth edge, until a termination of the second write interval, and
driving another write current through the cell in the second memory cell array, in a direction corresponding to a value of the latched second write data.

14. A resistive memory cell device, comprising
an address bus;
a control block configured to receive an externally generated address, a command and a clock and, in response, transmit an internal address on the address bus, and generate a first sub-bank address latch control and a second sub-bank address latch control;
a first sub-bank having a first array of resistive memory cells and a first sub-bank latching access circuitry that is configured to access a resistive memory cell in the first array of resistive memory cells according to a value of the internal address and maintain the access over a first interval based on the first sub-bank address latch control; and
a second sub-bank having a second array of resistive memory cells and a second sub-bank latching access circuitry that is configured to access a resistive memory cell in the second array of resistive memory cells according to an updated value of the internal address and maintain said access over a second interval based on the second sub-bank address latch control,
wherein the control block is configured to generate the first latch control and the second latch control so that the second interval overlaps the first interval.

15. The resistive memory cell device of claim 14, further comprising a data in port, a data in bus fed by the data in port, a data out bus, and a data out port fed by the data out bus,
wherein the first sub-bank further comprises a first sub-bank latching write driver having an input coupled to the data in bus and configured to receive a first sub-bank write latch control and, in response, to latch a value on the data in bus as a latched data in, and configured to receive a first sub-bank write enable and, in response, to drive a write current through the resistive memory cell accessed in the first array of resistive memory cells, based on a value of the latched data in, over the first interval,
wherein the second sub-bank further comprises a second sub-bank sense amplifier configured to receive a second sub-bank read enable and, in response, to drive the data out bus with a signal based on a state of the resistive memory cell accessed in the second array of resistive memory cells, and
wherein the control block is further configured to receive a write command and, and, in response to the write command and the external address corresponding to the first sub-bank, to generate the first sub-bank write latch control and the first sub-bank write enable.

16. The resistive memory cell device of claim 15, wherein the first array of resistive memory cells comprises a plurality of first array word lines and a plurality of first array bit lines, and resistive memory cells associated with intersections of the first array word lines and first array bit lines, and wherein the first sub-bank latching access circuitry comprises:
a first array row decoder configured to receive a row field of the internal address and, in response to a value of the row field, select a corresponding one of the first array word lines;
a first array word line latch configured to latch said corresponding one of the first array word lines at an enabled state over the first interval;
a first array bit line selector configured to receive a bit field of the internal address and, in response to a value of said bit field, to select a corresponding one of the first array bit lines; and
a first array bit line latch configured to latch said corresponding one of the first array bit lines at an enabled state over the first interval.

17. The resistive memory cell device of claim 16, wherein the second array of resistive memory cells comprises a plurality of second array word lines and a plurality of second array bit lines, and resistive memory cells associated with intersections of the second array word lines and second array bit lines, and wherein the second sub-bank latching access circuitry comprises:
a second array row decoder configured to receive the row field of the internal address and, in response to the value of the row field, to select a corresponding one of the second array word lines;
a second array word line latch configured to latch said corresponding one of the second array word lines at an enabled state over the second interval;
a second array bit line selector configured to receive the bit field of the internal address and, in response to the value of said bit field, to select a corresponding one of the second array bit lines; and
a second array bit line latch configured to latch said corresponding one of the second array bit lines at an enabled state over the second interval.

18. The resistive memory cell device of claim 14, wherein the first array of resistive memory cells comprises a plurality of first array word lines and a plurality of first array bit lines, and resistive memory cells associated with intersections of the first array word lines and first array bit lines, and wherein the first sub-bank latching access circuitry comprises:
a first sub-bank address latch having an input coupled to the address bus, and a first sub-bank address latch output;
a first array row decoder configured to receive a row field of the first sub-bank address latch output and, in response to a value of the row field, enable a corresponding one of the first array word lines; and
a first array bit line selector configured to receive a bit field of the first sub-bank address latch output and, in response to a value of the bit field, enable a corresponding one of the first array bit lines.

19. The resistive memory cell device of claim 18, wherein the control block is further configured to receive a clock having a sequence of a first edge, a second edge and a third edge spaced apart by a clock period;
receive, in association with the first edge, the externally generated address having a given value and, in response, transmit the internal address at a first value;
receive, in association with the second edge, the externally generated address having another given value and, in response, transmit the internal address at a second value; and
generate, prior to the second edge, in response to the given value of the externally generated address corresponding to the first sub-bank, the first sub-bank address latch control at a value that causes the first sub-bank address latch to latch the first value and provide the first value to the first array row decoder and to the first array bit line selector for the first interval, wherein the first interval extends past the second edge.

20. The resistive memory cell device of claim 19, further comprising a data in port, a data in bus fed by the data in port, a data out bus, and a data out port fed by the data out bus,
wherein the first sub-bank further comprises a first sub-bank latching write driver having an input coupled to the data in bus, configured to receive a first sub-bank write latch control and, in response, to latch a value on the data in bus as a latched data in, and configured to receive a first sub-bank write enable and, in response, to drive a write current through the enabled corresponding one of the first array bit lines, based on a value of the latched data in, over the first interval, and
wherein the control block is further configured to receive a write command and, in response to the write command and the external address corresponding to the first sub-bank, to generate the first sub-bank write latch control and the first sub-bank write enable.
